(19) United States
(12) Patent Application Publication
(10) Pub. No.: US 2018/0064199 A1
(43) Pub. Date: Mar. 8, 2018

(54) HELMET ACTIVE THERMO ELECTRIC COOLING SYSTEM AND METHOD

(71) Applicants: Robert D. Battis, Skillman, NJ (US); Wayne T. Armstrong, Placitas, NM (US)

(72) Inventors: Robert D. Battis, Skillman, NJ (US); Wayne T. Armstrong, Placitas, NM (US)

(73) Assignee: Extreme Laser Technologies, Inc., Princeton, NJ (US)

(21) Appl. No.: 15/695,877

(22) Filed: Sep. 5, 2017

Related U.S. Application Data
(60) Provisional application No. 62/383,677, filed on Sep. 6, 2016.
(60) Provisional application No. 62/397,596, filed on Sep. 21, 2016.

(51) Int. Cl. A42B 3/28; F21V 21/084; A42B 3/04; H01L 35/02; F28D 9/00

(52) U.S. Cl. CPC A42B 3/286; F21V 21/084; F28D 9/0093; A42B 3/0446; H01L 35/02; A42B 3/283

(57) ABSTRACT

Provided are active Thermoelectric Cooling (“TEC”) systems/apparatuses for the purpose of cooling a person's head with or without the person wearing a safety helmet or hard hat.

### CROSS REFERENCE TO RELATED APPLICATIONS

This application is related to and claims priority from U.S. Provisional Patent Application No. 62/383,677 filed on Sep. 6, 2016, by Robert D. Battis, et al. titled “Helmet Active Thermo Electric Cooling System and Method”, and also from U.S. Provisional Patent Application No. 62/397,596 filed on Sep. 21, 2016, by Robert D. Battis, et al. titled “Helmet Active Thermo Electric Cooling System and Method”, which are incorporated herein by reference in their entireties.

### FIELD OF THE INVENTION

This invention relates to an active system and method for cooling a person's head while allowing the person to wear protective head gear, or helmet, e.g.: soldier's helmet, motorcycle helmet, football helmet, hard hat, etc.

### BACKGROUND OF THE INVENTION

Adequately cooling a person's head while engaged in strenuous activity or in hot weather has always been a challenge, especially if protective head gear is worn, such as a helmet. In activities that require protective head gear such as riding a motor cycle, forestry, construction, industrial environments, military soldiers and sports, and the like, wearing a helmet and keeping a person's head cool is nearly impossible. Wearing current safety helmets can result in the head sweating, and can lead to a potentially dangerous heat build-up inside the helmet and human fatigue over time. In addition, some people do not wear a helmet to avoid the sweating and fatigue, hence placing their life in danger.

In the past, attempts have been made to provide partial cooling inside a helmet using several of the following passive techniques:
a. Creating holes in the helmet and hard hat (FIGS. 1a, 1b) to provide some convective air flow. In the case of hard hats where the person is stationary little cooling occurs due to lack of forced air within the helmet. And in addition helmet pads touching the head result in localized head sweating.
b. Designing the rim of the helmet with open spaces or cutouts so as to provide some convection air flow through the normally closed inside cavity of the helmet (FIG. 1c, 1d). This technique is either impractical or ineffective. It offers little improvement due to the spaces involved and helmet contact surfaces with the head.
c. Liquid phase change where a cloth, soaked in water is worn on the head (FIG. 1e) inside a helmet. As the water evaporates it removes heat from the head. One problem with this technique is water evaporation requires air flow inside the helmet, which involves the problem discussed in b) above.
d. Phase Change Material (PCM) cooling by inserting a pre-cooled or frozen pack (FIG. 1f) positioned directly to underside of helmet. The pre-cooled chemical inside the insert's flexible plastic covering changes phase thereby absorbing heat from the persons head. Pads come in different shapes. This approach avoids the air flow problems in b) and c) above but adds a considerable mass above the wearers head, increasing the height of the helmet. And in addition limits the cooling capacity and cooling time based on the size of the insert.

Thus, there is a need for a system and method for cooling a person's head while allowing the person to wear protective head gear, helmet, or the like which does not compromise the protective nature of the head gear, and also does not require empty spaces within the head gear or add considerable weight to the head gear.

### SUMMARY OF THE INVENTION

An aspect of the present invention provides for cooling a person's head while inside a helmet or hard hat, accomplished by active cooling using a Thermo Electric Cooling (“TEC”) apparatus or system comprised of one or a plurality of Thermo Electric (“TE”) Cooling chips herein referred to as a “TE Cooler”. The TE Cooler may take on several forms and physical implementations that result in head cooling as summarized in a-e:
a. With the TE Cooler being in contact with the head through a suitable thermally conductive cloth or membrane.
b. With the TE Cooler attached to the helmet but separated from the head with suitable cold fluid conducting tubing between the head and the TE Cooler.
c. With the TE Cooler remote from the helmet with suitable cold fluid conducting tubing between the head and Remote TE Cooler.
d. With the TE Cooler attached to the helmet but separated from the head with suitable air channel(s) directing cooled forced air from the TE Cooler to the head with the cooled air impinging on the head through a suitable cloth or membrane, having an open weave or holes.
e. With the TE Cooler remote from the helmet with suitable air channels directing cooled forced air from the TE Cooler to the head with the cooled air impinging on the head through a suitable cloth or membrane, having an open weave or holes.

In an aspect of the invention cooling a person's head may be by convection cooling by installing the TE Cooler on or within a hard hat and having a suitable fan circulate cool air within the hard hat or helmet and a suitable fan to dissipate heat from the TE Cooler and suitable temperature control electronics to maintain circulated air temperature by controlling TEC drive current and a suitable battery either mounted on the helmet or remote. This method of circulating cooled air to cool the head, having the TE Cooler on or within a hard hat, is referred herein as the “Convection Cooling method”.

In an aspect of the invention the TE Cooler is in contact with the head through a suitable thermally conductive band, or multiple bands, or cap, the elements of which are secured to the head or mounted inside the helmet, a suitable TEC heat dissipater and suitable fan to remove heat from the TEC, a suitable temperature control electronics to maintain head band temperature by controlling TEC drive current and a suitable battery either mounted on the helmet or remote. This method of cooling the head, having the TE Cooler in contact with the head, is referred herein as the “Direct Conduction” method.

In another aspect of the invention head temperature cooling occurs using a Fluid Thermal Electric Cooling (TEC) system contained within the helmet. This system includes TEC chip(s) mounted to a cold plate with a flexible fluid pipe delivering cooled fluid to a separate head band retaining the fluid in a closed-cycle configuration. The head band may consist of multiple bands, a cap worn on the head either secured to the head or mounted inside the helmet (helmet liner). The system also includes a suitable fan and separate radiator to remove heat from the TEC, a suitable pump to pump the closed cycle fluid between the TEC cold plate and head band and suitable temperature control electronics to maintain head band temperature by controlling fluid temperature by controlling TEC chip drive current and a suitable battery attached to the helmet or remote. This method of cooling the head using a fluid and having the TE Cooler separated from the head, is referred herein as the “Fluid Conduction method”.

In another aspect of the invention head temperature cooling occurs using a remote Fluid Thermal Electric Cooling (TEC) system. This system includes remote TEC chips imbedded in a cold plate which delivers cooled fluid to a separate head band retaining the fluid in a closed-cycle configuration. The head band may consist of multiple bands, a cap worn on the head either secured to the head or mounted inside the helmet (helmet liner). The system also includes a suitable pump to pump the closed cycle fluid between the TEC cold plate and head band and suitable temperature control electronics to maintain head band temperature by controlling fluid temperature by controlling TEC chip drive current and a suitable battery with the remote TEC unit. This method of cooling the head, having the TE Cooler separated from the head, is referred herein as the “Remote Fluid Conduction method”.

In another aspect of the invention head temperature cooling occurs using an Air Thermal Electric Cooling (TEC) system contained within the helmet. This system includes TEC chip(s) mounted to a suitable cooling radiator, a fan and flexible air pipe delivering cooled air to a separate head band which leaks the cooled air through the head band in an open-cycle configuration. The head band may consist of multiple bands, or cap worn on the head either secured to the head or mounted inside the helmet (helmet liner). The system also includes a suitable fan and separate radiator to remove heat from the TEC and suitable temperature control electronics to maintain head band temperature by controlling air temperature by controlling TEC chip drive current and a suitable battery attached to the helmet or remote. This method of cooling the head using air and having the TE Cooler separated from the head is referred herein as the “Air Conduction” method.

In another aspect of the invention head temperature cooling occurs using a remote Air Thermal Electric Cooling (TEC) system. This system includes remote TEC chip(s) mounted to a suitable cooling radiator, a fan and flexible air pipe delivering cooled air to a separate head band which leaks the cooled air through the head band in an open-cycle configuration. The head band may consist of multiple bands, or cap worn on the head either secured to the head or mounted inside the helmet (helmet liner). The system also includes a suitable fan and separate radiator to remove heat from the TEC and suitable temperature control electronics to maintain head band temperature by controlling air temperature by controlling TEC chip drive current and a suitable battery with the remote TEC unit. This method of cooling the head using air and having the TE Cooler remote from the head is referred herein as the “Remote Air Conduction method”.

In another aspect of the invention, TEC derived cooling is provided either directly or remotely to parts of the body other than the head such as a sprained ankle or knee or any area of the body that is swollen or bruised.

Another aspect of the invention provides TE derived cooling either directly, indirectly or remotely to the head while wearing a helmet, hat or cap such as a baseball cap.

In another aspect of the invention, TE derived cooling is provided to the head either directly, indirectly or remotely, with or without protective head gear such as a helmet or construction hard hat.

Another aspect of the invention provides for combining various aspects of Direct and Fluid Conduction TEC to allow instant cooling of the head band and with TEC heat removal using a cooled fluid pipe to replace the heat dissipater.

Another aspect of the invention provides for combining various aspects of Direct and Air Conduction TEC to allow instant cooling of the head band and with TEC heat removal using a forced cooled air pipe to replace the heat dissipater.

### BRIEF DESCRIPTION OF THE DRAWINGS

FIG. 1 show various prior art conventional passive cooling approaches discussed herein.

FIG. 2 illustrates a prior art single stage conventional Thermo Electric Cooling (hereinafter, “TEC”) chip operating on the Peltier principle

FIG. 3 illustrates an exemplary Convection Radiator that is useful for understanding the present invention.

FIG. 4 Hard Hat Convection TEC System illustrates an embodiment of the TE Cooler system operating within a safety hard hat that is useful for understanding the present invention. This system uses the convection air principle in which the TE Cooler complete convection system is attached to the hard hat.

FIG. 5 illustrates an embodiment of the Convection TEC Head Band System on a soldier that is useful for understanding the present invention.

FIG. 6 illustrates an exemplary head band with attached TEC chips (direct conduction) that is useful for understanding the present invention.

FIG. 7 illustrates an embodiment of the Direct Conduction TEC Head Band System that is useful for understanding the present invention.

FIG. 8 illustrates an exemplary head band that is useful for understanding the Fluid Conduction method of the present invention.

FIG. 9 illustrates an embodiment of the Fluid Conduction TEC Head Band System that is useful for understanding the present invention.

FIG. 10 illustrates an embodiment of a compact TEC Heat Exchanger used in the Fluid Conduction TEC Head Band System that is useful for understanding the present invention.

FIG. 11 illustrates test hardware that is one embodiment of the Fluid Conduction TEC Head Band System that is useful for understanding the present invention.

FIG. 12 illustrates an embodiment of the Fluid Conduction TEC Head Band System on a safety hard hat that is useful for understanding the present invention. This system uses the fluid thermal conduction principle in which the TE Cooler complete system is attached to the hard hat top, with the exception of the battery.

FIG. 13 illustrates an embodiment of the Fluid Conduction TEC Head Band System on a safety construction hard hat that is useful for understanding the present invention. This embodiment uses the same principles and similar hardware as that in FIG. 12 except the TE Cooler is split into two parts and symmetrically mounted low on the helmet sides.

FIG. 14 illustrates two types of heat dissipaters which may be used in various Convection and Conduction TEC Systems.

FIG. 15 illustrates an embodiment of a remote variant of the TE Cooler Fluid Conduction TEC System that is useful for understanding the present invention.

FIG. 16 illustrates an embodiment of the Remote Fluid Conduction TEC System on a soldier that is useful for understanding the present invention.

FIG. 17 illustrates an exemplary head band that is useful for understanding the Air Conduction method of the present invention.

FIG. 18 illustrates an embodiment of the Air Conduction TEC Head Band System that is useful for understanding the present invention.

FIG. 19 illustrates an embodiment of a remote variant of the TE Cooler Air Conduction TEC System that is useful for understanding the present invention.

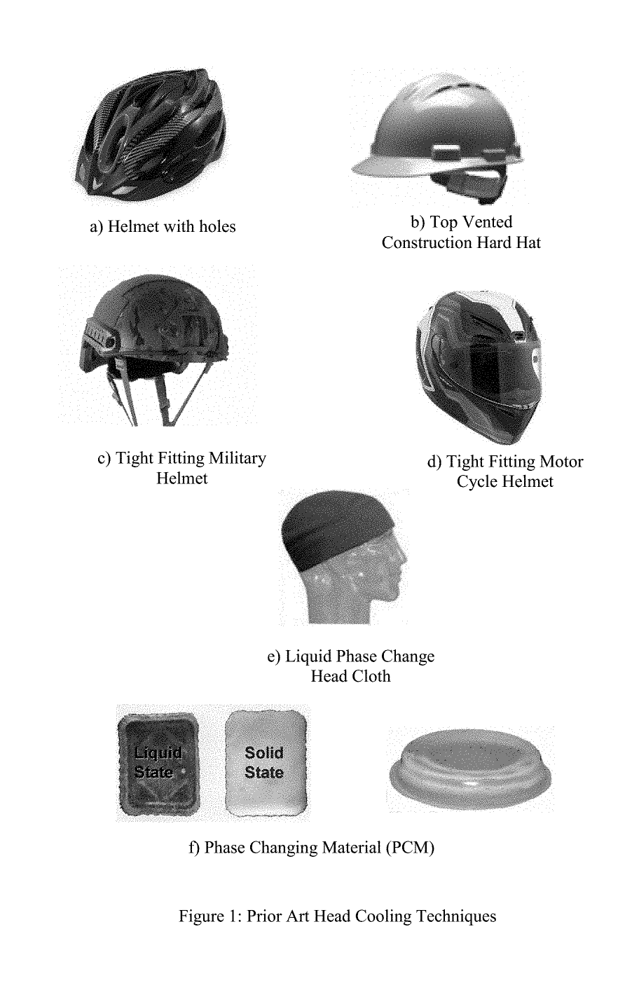

### DETAILED DESCRIPTION

In the following description, for purposes of explanation, specific numbers, materials and configurations are set forth in order to provide a thorough understanding of the invention. It will be apparent, however, to one having ordinary skill in the art, that the invention may be practiced without these specific details. In some instances, well-known features may be omitted or simplified so as not to obscure the present invention. Furthermore, reference in the specification to “one embodiment” or “an embodiment” means that a particular feature, structure or characteristic described in connection with the embodiment is included in at least one embodiment of the invention. The appearances of the phrase “in an embodiment” in various places in the specification are not necessarily all referring to the same embodiment.

Cooling a person's head may be done by thermal convection, thermal conduction or a combination. Thermal convection in this context is defined as transfer of cold from one medium to another by circulating air and thermal conduction is defined as transmission of cold through a conducting medium.

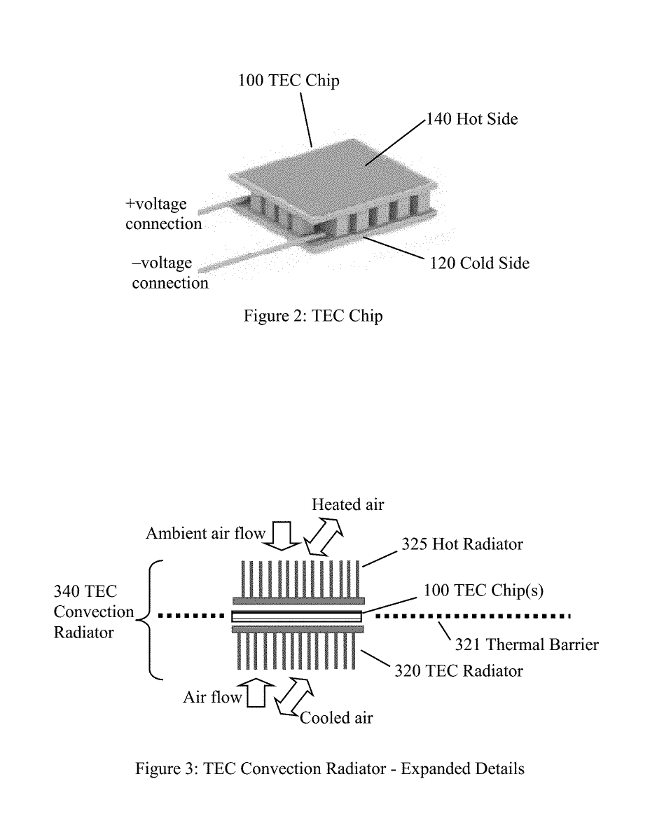

FIG. 2 illustrates a single stage conventional Thermo-Electric Cooler (hereinafter, “TEC”) chip, also known as a Peltier element. TEC operates according to the Peltier effect. The effect creates a temperature difference by transferring heat between two electrical junctions. A voltage is applied across joined conductors to create an electric current. When the current flows through the junctions of the two conductors, heat is removed at one junction, Cold Side 120, and cooling occurs, while heat is transferred to the opposite junction, Hot Side 140. Many TEC chips are combined to form a TEC assembly and an assembly may be combined with other items, such as thermal conducting sheets, heat dissipater and battery to form a complete system. It is also noteworthy that reversing the direction of current flow effectively acts to reverse the direction of heat transfer, so that the cooling apparati described herein may alternatively operate as a heating apparatus, in many cases.

FIG. 3 illustrates an exemplary construction of a TEC Convection system radiator in which one or more TEC chips 100 (see, FIG. 2) are sandwiched between two radiators, Hot Radiator 325 and TEC Radiator 320. Excess heat from the Hot Side 140 of the TEC Chip 100 is controlled/removed by blowing ambient air across the Hot Radiator 325. The Cold Side 120 of the TEC Chip 100 cools the TEC Radiator 320. By blowing air across or circulating air around the TEC Radiator 320 this air is cooled. By creating a Thermal Barrier 321 between these two radiators the cooled air zone may be isolated from ambient air. The construction of one or more TEC chips 100 sandwiched between two radiators (Hot Radiator 325, TEC Radiator) is referred to as the TEC Convection Radiator 340. Blowing air across these radiators may be accomplished by one or more fans as separate parts or incorporated into the TEC Convection Radiator 340. Any suitable type of heat dissipater, such as but not limited to as illustrated in FIG. 14 may be used for either the Hot Radiator 325 or TEC Radiator 320.

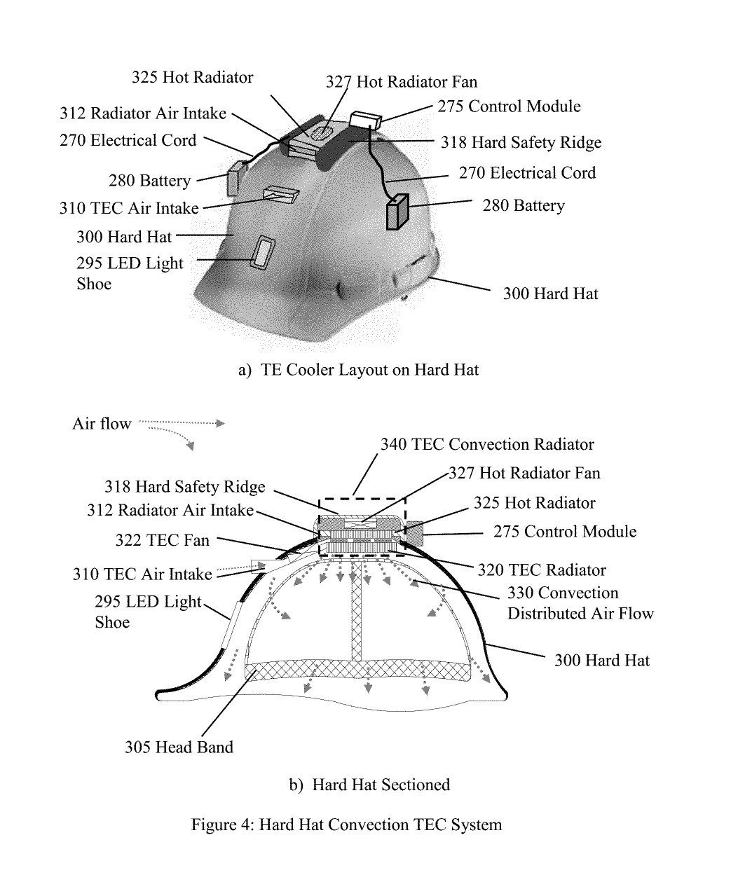

An embodiment of the present invention advantageously provides for convection head cooling (FIG. 4) as illustrated with a Hard Hat 300. This is referred to as the Hard Hat Convection TEC System. Convection cooling is accomplished by locating a TEC Convection Radiator 340 (see, FIG. 3) on top of the hard hat and using the hard hat shell as the Thermal Barrier 321. In this exemplary configuration two fans are used. The Hot Radiator 327 fan is located above the Hot Radiator 325 directing ambient air from the Radiator Air 312 Intake through the Hot Radiator 325. The TEC Fan 322 is located inside the hard hat directing air from the TEC Air Intake 310 across the TEC Radiator 320 thereby creating Convection Distributed Air Flow 330 around the wearers head in an open-cycle configuration. This air flow exits the hard head circumferentially at the hard hat bottom. The detailed design of the TEC Radiator 320 is critical in achieving suitable Convection Distributed Air Flow 330. This design may include, but is not limited to staggered aluminum or other metals such as copper fins, deflection partitions, distributed holes of varying sizes, or a combination of these. It is understood that the configuration illustrated in FIG. 4 is only one of many possible configurations resulting in one or more air intakes and one or more fans.

In this embodiment of the Hard Hat Convection TEC System (FIG. 4) convection cooling may be enhanced by a special construction of the typical 305 Head Band. The Head Band 305 may be constructed as a thermally conductive open weave material. This head band will then be cooled by the convection air flow and in turn aid head cooling by the conduction principle. The band width and number of bands may be varied to increase or decrease this thermal conduction effect.

The Hard Hat Convection TEC System (FIG. 4) has mounted on the Hard Hat 300 other parts which comprise a total system—Battery 280, Control Module 275. The Battery 280 is split into two equal parts and the Control Module 275 is conveniently mounted on the rear centerline of the Hard Hat 300. This arrangement of parts allows the Hard Hat 300 to remain balanced. The Electrical Cords 270 are conveniently routed from each battery to the Control Module 275 either on top of the hard hat or internal. The electrical wiring between the Control Module 275 and fans/TEC Convection Radiator 340 are conveniently routed inside the Hard Hat 300. As an option an auxiliary battery port may be added to the Control Module 275 for extended use using a remote battery pack, or to use a remote battery only.

In this embodiment of the hard hat TEC convection TEC System the hard hat protective envelope is violated with the protrusion of the top module consisting of the Radiator Intake 312, Hot Radiator Fan 327 and all or part of the Hot Radiator 325. This situation is corrected by providing several Hard Ridges 318 on top of the Hard Hat 300 that extend slightly above the top protrusion discussed. If an object were to fall on the hard hat, or the hard hat was to impact an object above these Hard Ridges 318 would absorb the impact force. Other arrangements to protect against impact are also possible.

Cold temperature control of Hard Hat Convection TEC System may be accomplished by a preset temperature built in to the electronics or preferably by an adjustment control mounted on the Control Module 275. This temperature control utilizes inputs from thermistors or other electronic parts mounted on the TEC Radiator 320 and/or Hot Radiator 325 and/or within the Convection Distributed Air Flow 330. This adjustment control may take on various forms, such as but not limited to a sliding or rotating potentiometer, preset switch contact positions or buttons. In addition, the on-off control for the Hard Hat Convection TEC System may be incorporated into the cold temperature control or may be a separate switch.

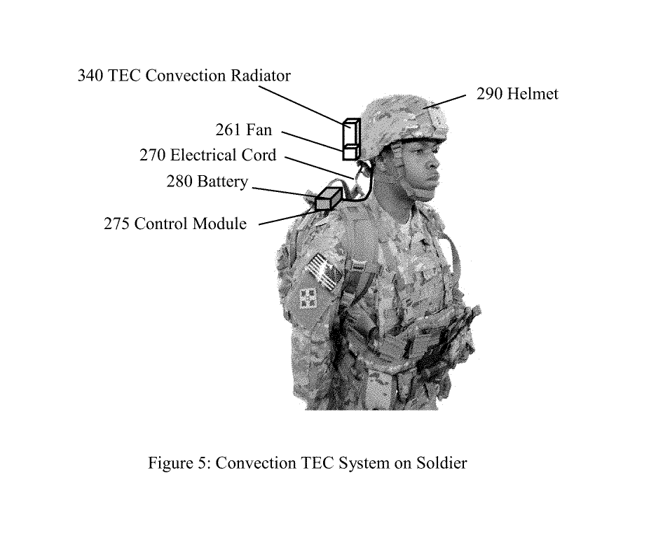

In FIG. 5, an exemplary Convection TEC System is illustrated on a soldier with the TEC Convection Radiator 340 with a Fan 261 located on the back of the helmet. With this one fan arrangement, the air ducting is configured to split incoming air and divert a percentage across the Hot Radiator 325 and the remainder across the TEC Radiator 320 into the Helmet interior 290. The Battery 280 and Control Module 275 are combined and attached on top of the Soldiers backpack. The Electrical Cord 270 routed up the rear of the helmet connects the Battery 280 and Control Module 275 to the TEC Convection Radiator 340 and Fan 261. In another arrangement the Control Module 275 may be located on the Soldiers Helmet.

A LED Light 295 shoe (FIG. 4) may be provided on the Hard Hat 300 to conveniently attach a commercial LED light product.

A chin strap may be provided in the FIG. 4 hard hat functionally similar to the military chin strap shown in FIG. 5. These chin straps of various designs are readily available commercially.

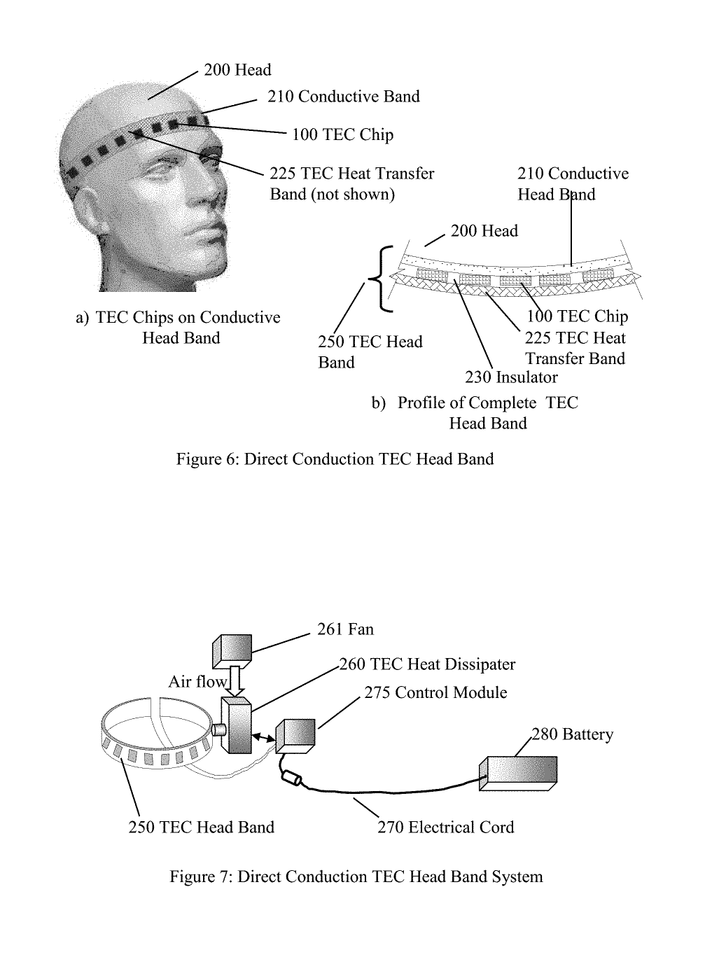

An embodiment of the present invention advantageously provides for Direct Conduction head cooling. This is accomplished by direct contact of TECs imbedded in a suitably designed flexible thermally conductive TEC Head Band 250 that wraps around the Head 200 (FIG. 6). This head band consists of a thermally conductive flexible Conductive Band 210 with a plurality of TEC Chips 100 and a top flexible TEC Heat Transfer Band 225. Each TEC chip consists of a Cold side 120 (FIG. 2) attached to the Conductive Head Band 210 (FIG. 6). The TEC Chip Hot Side 140 (FIG. 2) is attached to the TEC Heat Transfer Band 225. Nestled between and around each TEC Chip 100 is a piece of a Insulator 230. This insulator isolates the Conductive Band 210 inner side from the Heat Transfer Band 225 thereby preventing thermal conduction. The TEC Head Band 250 is illustrative of one embodiment; others may include multiple bands or a cap or a helmet liner with distributed TEC chips.

An embodiment of the present invention described in FIG. 6 advantageously provides for a complete system called Direct Conduction TEC Head Band System illustrated in FIG. 7. The complete Direct Conduction TEC Head Band System comprises the TEC Head Band 250 (FIG. 6), TEC Heat Dissipater 260, Fan 261, Control Module 275, Electrical Cord 270 and Battery 280.

In one embodiment the TEC Heat Transfer Band 225 (FIG. 6) is suitably attached by a thermally conductive path to a TEC Heat Dissipater 260 (FIG. 7). The Heat Dissipater 260 may take on various forms based on various technology implementations. This Heat Dissipater 260 may comprise but is not limited to helmet fins, separate fins, a fan or thermal transfer via a fluid or air. For example, the flexible TEC Heat Transfer Band 225 may be a flat thermally conductive tube with an internal rough surface in which a fluid is circulated by the TEC Heat Dissipater 260. The TEC Heat Dissipater 260 would then expel this heat into the environment using a suitable attached radiator and fan.

Referring to FIG. 7 in this Direct Conduction TEC Head Band System the head is cooled to a preset temperature by controlling the current through the TEC chip(s). This current is controlled by the Control Module 275 which monitors the head band temperature using a head band imbedded thermistor or other suitable electronic temperature monitor.

Although the TEC Chips on the Conduction Head Band illustrated in FIG. 6a, namely the TEC chips 100 on the Conductive Head Band 210 is shown as one row of TEC chips 100, it is understood that this is only one physical implementation or embodiment of the concept. Other embodiments of TEC chips on the head are possible, such as multiple bands or a cap or a helmet liner with distributed TEC chips. In addition, the concept can be expanded to include TE Coolers distributed to other parts of the body, on the neck for example. In another embodiment of the Conduction TEC Head Band the TEC Head Band 250 may be expanded to include more than one head band or a cap, attached to the inside liner of the helmet and which remains in contact with the head when the helmet is worn.

In another embodiment of the Direct Conduction TEC Head Band System the above elements may be worn without a helmet, or with a hat or cap such as a baseball cap.

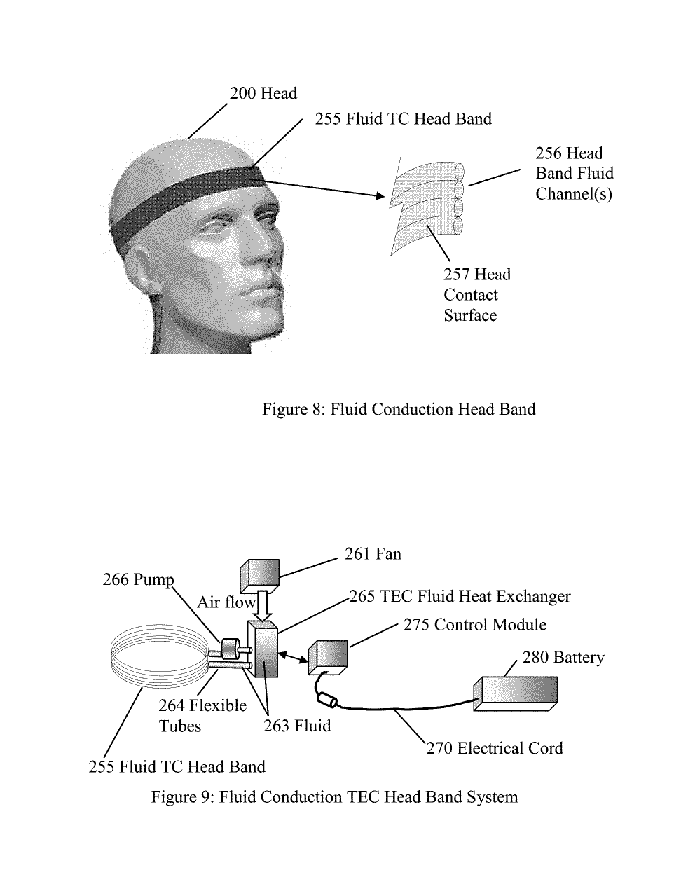

An embodiment of the present invention advantageously provides for Fluid Conduction head cooling. This is accomplished by creating a special flexible Thermally Conductive (“TC”) Fluid TC Head Band 255 (FIG. 8) worn around the Head 200. This head band contains one or more Head Band Fluid Channel(s) 256. The Head Contact Surface 257 of the Fluid TC Head Band 255 is thermally conductive while the outer (opposite) side has a preferred thin layer of insulation. The fluid inside the Fluid TC Head Band 255 is cooled and circulates through this head band and accompanying apparatus in a closed cycle configuration. This cooled fluid then cools the wearers head through the Fluid TC Head Band 255 using the conduction principle. The Fluid TC Head Band 255 is illustrative of one embodiment; others may include multiple bands or a cap or a helmet liner.

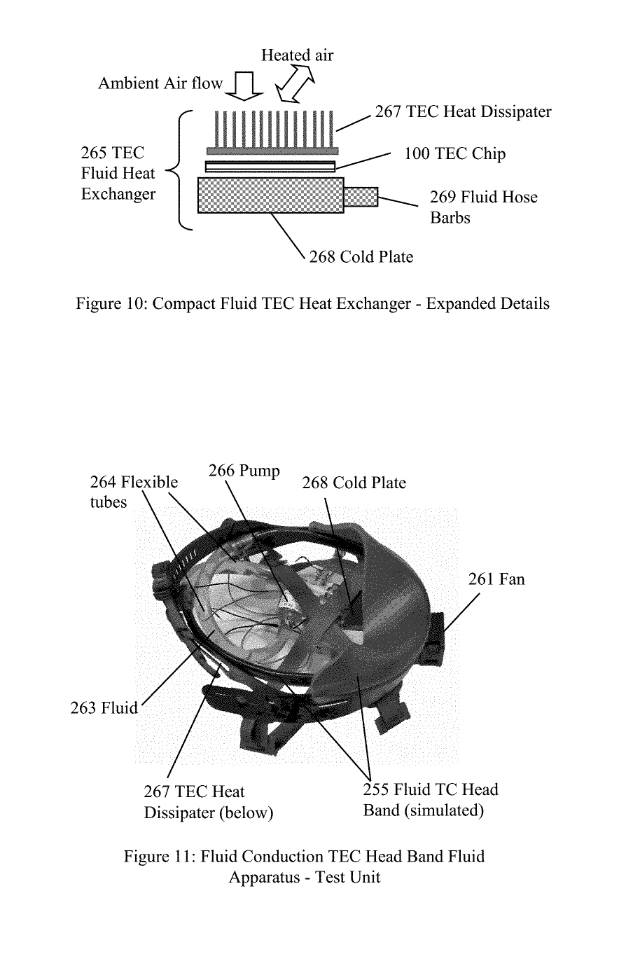

An embodiment of the present Fluid Conduction head cooling invention described in FIG. 8 advantageously provides for a complete system called Fluid Conduction TEC Head Band System illustrated in FIG. 9. The complete Fluid Conduction TEC Head Band System comprises the Fluid TC Head Band 255 (FIG. 8), Pump 266, Flexible tubes 264, Fluid 263, TEC Fluid Heat Exchanger 265, Fan 261, Control Module 275, Electrical Cord 270 and Battery 280. The TEC Fluid Heat Exchanger 265 is further described in FIG. 10.

In one embodiment of Fluid Conduction cooling, as illustrated in FIG. 9 the Fluid TC Head Band 255 is suitably attached to Flexible tubes 264 and the tubes in turn are attached to a Pump 266 and TEC Fluid Heat Exchanger 265. This arrangement creates a very compact closed cycle path for the cooled Fluid 263. This compact path is further illustrated by the test hardware shown in FIG. 11. The Fluid 263 may be any thermally conductive fluid such as water, optionally with a small percentage of chemical additives. In addition to the closed-cycle cooled fluid path there is a Fan 261 that controls/removes heat from the TEC Heat Dissipater 267 (FIG. 10).

The Control Module 275, Electrical Cord 270 and Battery 280 completes the Fluid Conduction TEC Head Band System (FIG. 9). Having separate control module and battery is only one physical implementation of the concept. Other implementations are possible such as combining both or splitting the battery in several parts.

Referring to FIG. 9 in this Fluid Conduction TEC Head Band System the head is cooled to a preset temperature by controlling the Fluid TC Head Band 255 and/or Fluid 263 using an imbedded thermistor or other suitable electronic temperature monitor. The temperature is controlled by controlling the current into the 100 TEC Chip 263 (FIG. 10) by the Control Module 275.

The compact TEC Fluid Heat Exchanger 265 (FIG. 10) is a key assembly in the Fluid Conduction head cooling invention. The TEC Chip 100 is thermally sandwiched between the TEC Heat Dissipater 267 and Cold Plate 268. In this application any suitable heat dissipater may be used with preferably thin fins as illustrated in FIG. 14. In this application any suitable cold plate, sometimes referred to as a water block may be used, but the preferred design incorporates Fluid Hose Barbs 269 and minimizes the internal fluid pressure drop.

The Fluid Conduction TEC Head Band System illustrated in FIG. 9 was implemented in a working set of test hardware as shown in FIG. 11. This test unit is extremely compact and contains all the closed cycle fluid parts and fan illustrated in FIG. 9.

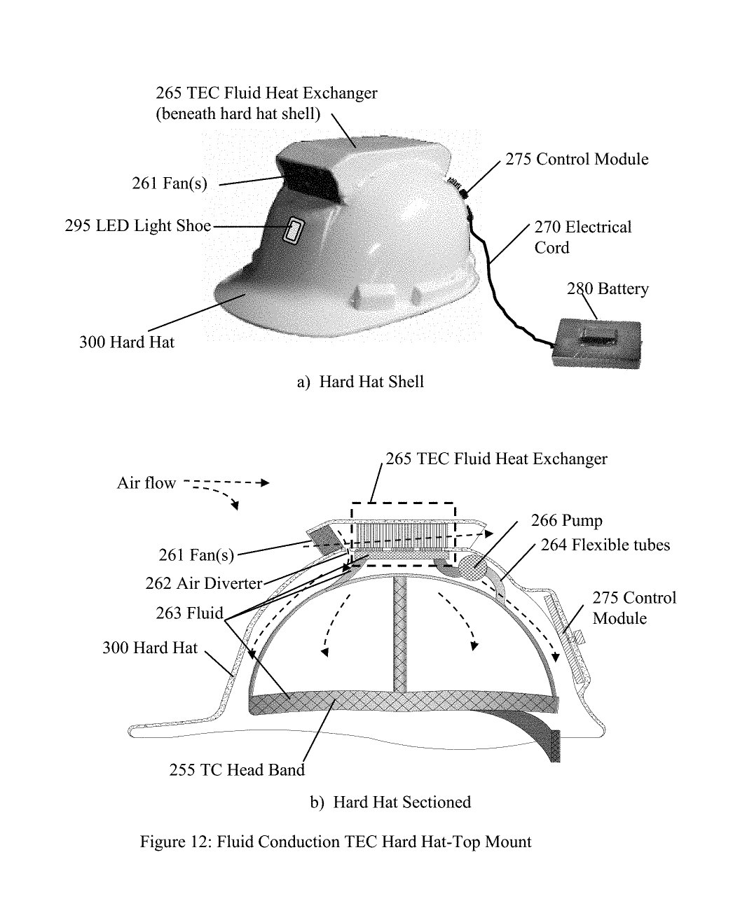

An embodiment of the present invention advantageously provides for a Fluid Conduction TEC Hard Hat, as illustrated in FIG. 12. This is accomplished by assembling the Fluid Conduction TEC Head Band System of FIG. 9 into a hard hat. The key compact fluid parts plus fan of FIG. 9 is also shown in hardware form in FIG. 11. As FIG. 12a shows the TEC Fluid Heat Exchanger 265 is mounted or imbedded in the top of the Hard Hat 300 with the Fan 261 mounted in front. This configuration is referred to as the Top Mount. The Control Module 275 is mounted at the rear on the helmet center line. This parts arrangement maintains helmet balance. In addition to the TEC system parts a LED Light 295 shoe may be provided on the Hard Hat 300 to conveniently attach a commercial LED light product. A commercial chin strap (not illustrated) may also be attached in the normal and customary way. The Battery 280 is shown as a remote part with a electrical Cord 270 connecting it to the Control Module 275. A remote battery is only one of several options.

A key feature of the Fluid Conduction TEC Hard Hat, as illustrated in FIG. 12b is the Air Diverter 262. By locating the Fan 261 in front of the TEC Fluid Heat Exchanger 265 an air path may be provided to divert a small percentage of ambient air into the hard hat interior space. This air flow means a small positive pressure difference will exist inside the hard hat which will reduce or eliminate the humid stagnant air situation that normally occurs around wearers head. This Air Diverter 262 may be blocked in dusty environments to prevent dust from accumulating inside the hard hat.

A distinct advantage of the compact modular and complete Fluid Conduction TEC Head Band Fluid Apparatus (FIG. 11) means it can be installed from inside the hard hat. This allows the Hard Hat 300 (FIG. 12a) to be molded as one part preserving the impact resistance of a rigid shell.

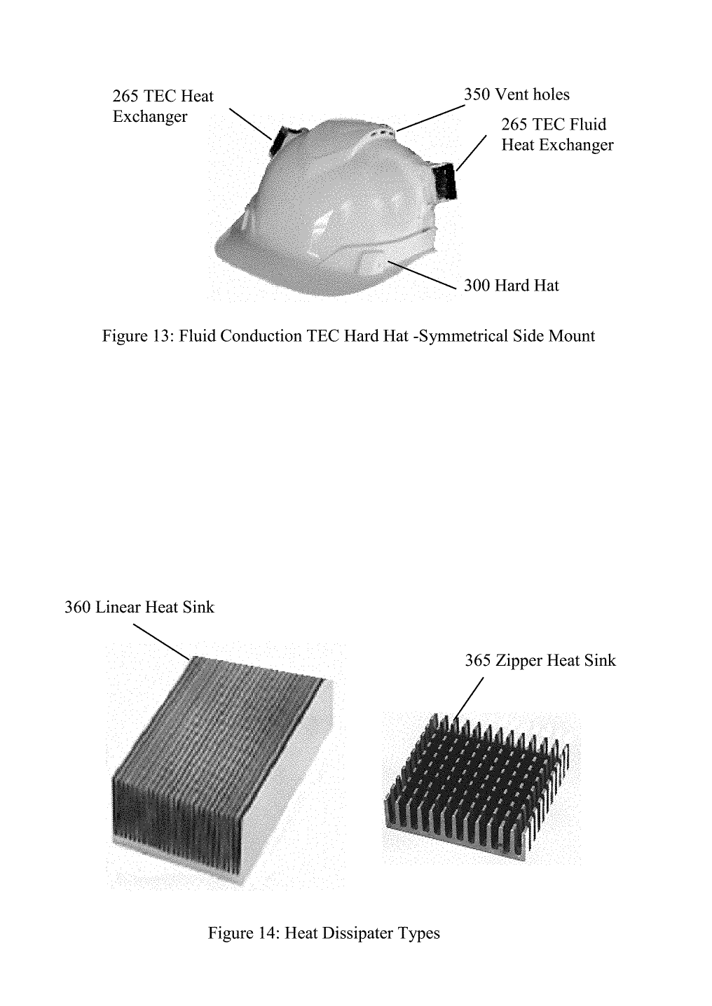

Another embodiment of the present invention advantageously provides for several other version of the Fluid Conduction TEC Head Band System. One of these called the Symmetrical Side Mount is illustrated in FIG. 13. In this version the TEC Fluid Heat Exchanger 265 (FIG. 10) may be made smaller (scaled down) and this smaller TEC Fluid Heat Exchanger 265 is mounted on each side of the Hard Hat 300 close to the bottom hard hat rim. All other aspects of the Fluid Conduction TEC Head Band System of FIG. 9 are the same for this Symmetrical Side Mount version. For this configuration the Zipper Heat Sink 365 (FIG. 14) is preferred for the Heat Dissipater 267 (FIG. 10). The Control Module 275 mounted at the rear of the Hard Hat 300 remains unchanged. Vent Holes 350 (FIG. 13) may be provided for air circulation with or without a tinny internal fan to enhance this circulation.

Another version of the Fluid Conduction TEC Head Band System is referred to as the Unsymmetrical Side Mount_(not illustrated). In this version a TEC Fluid Heat Exchanger 265 (FIG. 10) (scaled down or not) is mounted on one side of the Hard Hat 300 (FIG. 13) and to balance the Hard Hat 300 the TEC Fluid Heat Exchanger 265 on the opposite side (FIG. 13) is replaced by a suitable sized and weight battery. The Control Module 275 mounted at the rear of the Hard Hat 300 remains unchanged. This Unsymmetrical Side Mount version of the Fluid Conduction TEC Head Band System is ideally suited for short term use, such as job site or mine inspections.

In yet another version of the Unsymmetrical Side Mount (not illustrated), the TEC Fluid Heat Exchanger 265 may be mounted on the hard hat rear with the weight balanced by appropriately mounting batteries and electronics on both sides of the hard hat 300 towards the hard hat front.

Another embodiment of the present invention advantageously provides for Fluid Conduction TEC Head Band System mounted on a military helmet 290 (FIG. 16). This helmet application is exactly the same as the hard hat approach of FIG. 12 or 13 with the TEC Fluid Heat Exchanger 265 mounted either on top, sides or on the rear of the Helmet 290.

Cold temperature control of Helmet or Hard Hat Conduction TEC Systems operation may be accomplished by a preset temperature built in to the electronics or preferably by an adjustment control mounted on the Control Module 275 (FIGS. 7, 9) This temperature control utilizes inputs from thermistors or other electronic parts mounted on or within the TEC Head Band 250, Fluid TC Head Band 255 and in the Fluid 263.

Temperature adjustment control may take on various forms, such as but not limited to a sliding or rotating potentiometer, preset switch contact positions or buttons. In addition, the on-off control for the TE Cooler may be incorporated into the cold temperature control or may be a separate switch or may be incorporated into the battery.

In a further embodiment of the cold temperature/on-off control, the Hard Hat/Helmet Conduction TEC Systems may incorporate heating instead of cooling. This is accomplished by simply reversing the current through the TEC Chip(s) 100. Control of this heating mode may be incorporated into the cold temperature/on-off control or may be a separate control, with or without LED indicators.

In a further embodiment of the cold temperature/on-off control, the Hard Hat Convection TEC System may incorporate heating instead of cooling. This is accomplished in the same manner as described for the Hard Hat/Helmet Conduction TEC System.

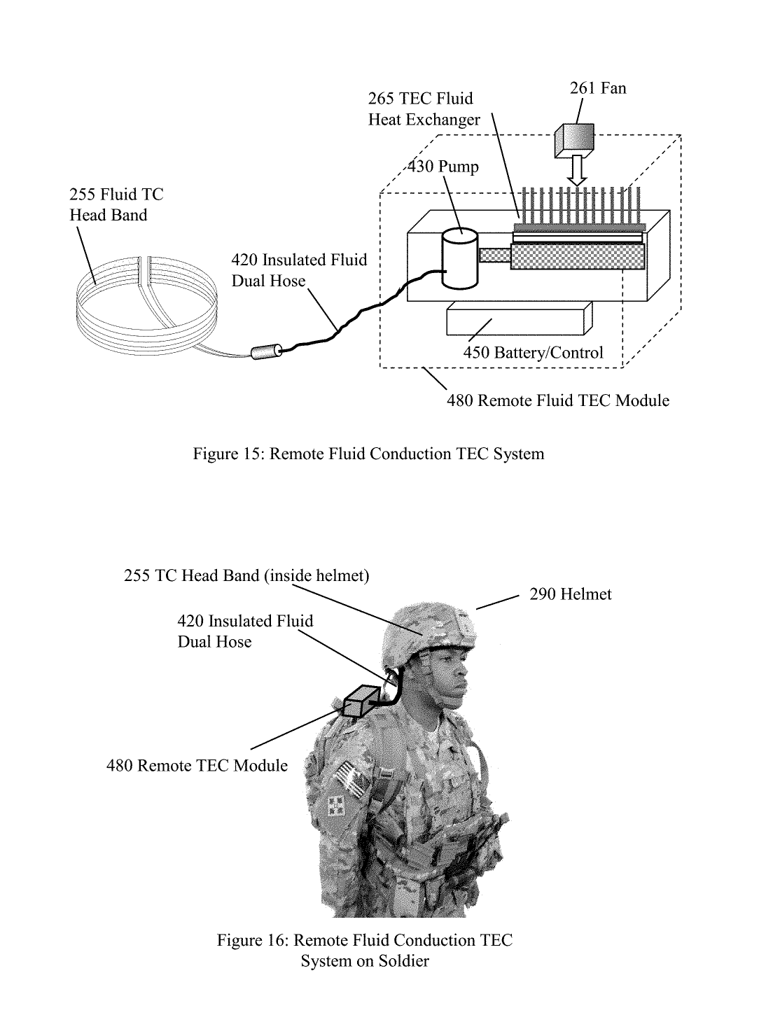

Another embodiment of the present invention advantageously provides for conduction head cooling by Remote Fluid Conduction TEC System (FIG. 15). In this remote variant the TEC Fluid Exchanger 265 (FIG. 10) demonstrated for use in a hard hat (FIG. 12) is incorporated in the Remote Fluid TEC Module 480 and operated remote from the hard hat. The Remote Fluid TEC Module 480 incorporates a Fan to cool 261 the TEC chip(s) 100, a Pump 430 to pump the fluid through a Insulated Dual Hose 420 to the Fluid TC Head Band 255 in the hard hat and a Battery/Control 450. The chilled fluid, circulating in a closed cycle configuration cools the Head 200 by conduction through the Fluid TC Head Band 255 (FIG. 8). The TEC Fluid Exchanger 265 design (FIG. 15) is scalable to meet the thermal demands of a remote system and a specific field application.

The TEC Fluid Exchanger 265 (FIG. 10) used in the Remote Fluid TEC Module 480 (FIG. 15) may be replaced by any commercial cold Plate/radiator. These commercial units may consist of a plurality of TEC Chips 100 attached to a thermally conductive plate to which is attached a serpentine pipe through which a liquid flows to the Pump 430 in a closed cycle configuration.

Fluid temperature is maintained in the Remote Fluid Conduction TEC System (FIG. 15) by the Battery/Control unit 450 at a preset level by controlling the current through the TEC Fluid Exchanger 265 TEC chip(s) 100. The fluid temperature is monitored using a thermal couple or similar device imbedded in the return Insulated Fluid Dual Hose 420. Heat is controlled/removed from the TEC Heat Dissipater 267, which is part of the TEC Fluid Heat Exchanger 265 (FIG. 10) by a Fan 261. In some enbodiments the Fan 261 may be optional.

FIG. 16 illustrates and exemplary Remote Fluid Conduction TEC System on a soldier with the Fluid TC Head Band 255 (FIG. 8, 15) inside the helmet, the Remote Fluid TEC Module 480 attached on top of the Soldiers backpack and the Insulated Fluid Dual Hose 420 routed up the rear of the helmet connecting the Remote Fluid TEC Module 480 to the Fluid TC Head Band255.

Although the Fluid Conduction TEC System Fluid TC Head Band 255 (FIGS. 8, 9, 11, 12, 15) is shown as one integral multi-channel band, it is understood that this is only one physical implementation or embodiment of the concept. Other arrangements of fluid channels on the head are possible, such as a multiple bands or fluid filled cap. In addition the concept can be expanded to include cold fluid channels to other parts of the body, on the neck for example.

In another embodiment of the Remote Fluid Conduction TEC System (FIG. 15), the Fluid TC Head Band 255 may be worn without a helmet, or with a hat or cap such as a baseball cap.

In another embodiment of the Direct Conduction TEC Head Band Systems (FIGS. 7, 9) the Fluid TC Head Band 255 may be combined with the TEC Head Band 250 by sandwiching the TEC Head Band 250 (FIG. 6) as the inner layer closest to the person with the Fluid TC Head Band 255 (FIG. 8) as the outer layer. This hybrid combination has the advantage of using the Fluid TC Head Band 255 to remove the heat from the TEC Chips thereby eliminating the need for a separate TEC Heat Dissipater 260 (FIG. 7). With this hybrid combination the TEC Heat Dissipater 260 (FIG. 7) is replaced with the TEC Fluid Heat Exchanger 265 and the Control Module 275 (FIG. 9) redesigned to control 2 different sets of TEC Chips 100 (FIG. 2). In yet another hybrid version the TEC Fluid Heat Exchanger 265 (FIG. 9) may be replaced with the Remote Fluid TEC Module 480 (FIG. 15).

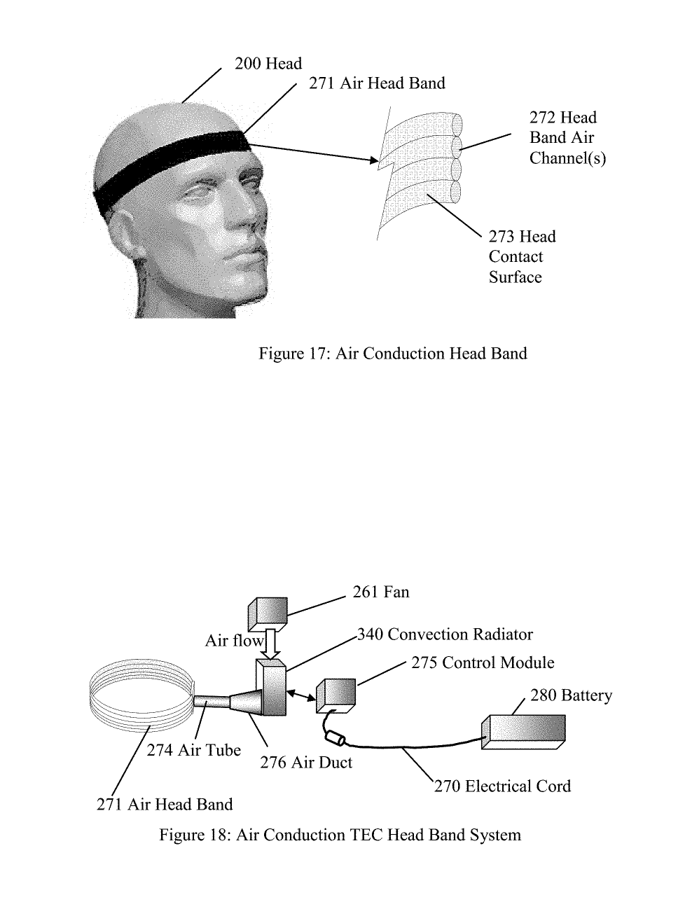

An embodiment of the present invention advantageously provides for Air Conduction head cooling. This is accomplished by creating a special flexible Air Head Band 271 (FIG. 17) worn around the Head 200. This head band contains Head Band Air Channel(s) 272 (one or more) and is constructed on one side as a loose weave or with holes to expel the air. The head band has an asymmetrical construction with the Head Contact Surface 273 having the loose weave or holes and the outer (opposite) surface preferably being non-porous. The air inside the Air Head Band 271 is cooled and flows under moderate pressure in an open-cycle configuration. This cooled air then impinges on the wearers head through the Air Head Band 271 and exits the helmet bottom. The Air Head Band 271 is illustrative of one embodiment; others may include multiple bands or a cap or a helmet liner.

An embodiment of the present Air Conduction head cooling invention described in FIG. 17 advantageously provides for a complete system called Air Conduction TEC Head Band System illustrated in FIG. 18. The complete Air Conduction TEC Head Band System comprises the Air Head Band 271 (FIG. 17), flexible Air Tube 274, Air Duct 274, Convection Radiator 340, Fan 261, Control Module 275, Electrical Cord 270 and Battery 280. The TEC Radiator 320 (FIG. 3) provides the cooled air and this air is channeled by the Air Duct 276 through the Air Tube 274 to the Air Head Band 271. The Fan 261 (FIG. 18) may in fact be one fan removing heat from the Hot Radiator 325 (FIG. 3) as well as supplying the forced air through the TEC Radiator 320 and Air Duct 276 (FIG. 18) or the fan may be split into two with each servicing only one radiator.

The Air Conduction TEC Head Band System (FIG. 18) may be incorporated into any hard hat or helmet as in the Fluid Conduction TEC Hard Hat—Top Mount example of FIG. 12.

Referring to FIG. 18 in this Air Conduction TEC Head Band System the head is cooled to a preset temperature by controlling the air temperature in the Air Tube 274 or Air Duct 276 or Air Head Band 271. The air temperature is controlled by controlling the current into the TEC Chip 100 (FIG. 3). This current is controlled by the Control Module 275 which monitors the air temperature using an imbedded thermistor or other suitable electronic temperature monitor.

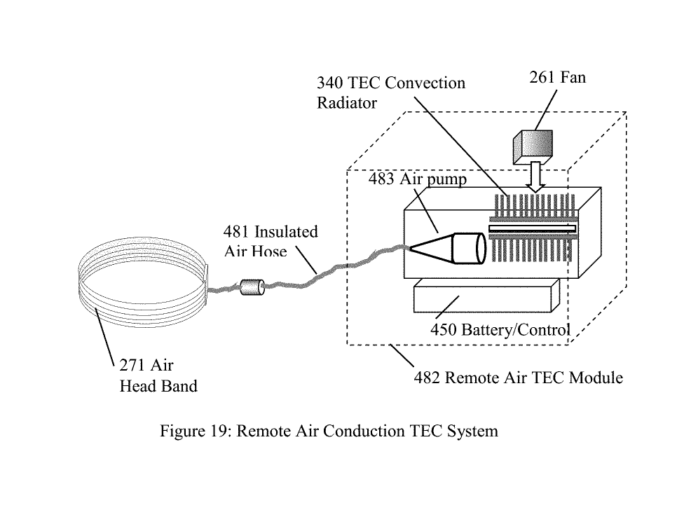

Another embodiment of the present invention advantageously provides for remote conduction head cooling by Air active cooling provided by a Remote Air TEC Module 482 (FIG. 19). Within this module TEC is provided by the TEC Convection Radiator 340 (FIG. 3) operating through an Air Pump 483, Insulated Air Hose 481 to a Air Head Band 271 (FIG. 17). The cold air under moderate pressure trickles through the Head band air channels 272 thereby cooling the Head 200 (FIG. 17) in an open-loop configuration.

Air temperature is maintained in the Remote Fluid Conduction TEC System (FIG. 19) by the Battery/Control unit 450 at a preset level by controlling the current through the TEC chip(s) 100 which is part of the TEC Convection Radiator 340 (FIG. 3). The air temperature is monitored using a thermal couple or similar device imbedded in either the Air Pump 483, Insulted Hose 481 or Air Head Band 271. Heat is controlled/removed from the Hot Radiator 325 (FIG. 3) with a Fan 261. In some designs the Fan 261 may be optional.

The Remote Air Conduction TEC System (FIG. 19) may be incorporated in a soldier's helmet and back pack in a similar way as shown for the Remote Fluid Conduction TEC System on a soldier (FIG. 16).

The Convection TEC System (FIGS. 3, 4) and Conduction Head Band Systems (FIGS. 7, 9, 10, 18) and the Remote Conduction TEC Systems (FIGS. 15, 19) use TEC chips such as depicted in FIG. 2, but these chips may be different in size, power and numbers. But in all cases it is anticipated the TEC Chips 100 will be a single stack as illustrated in FIG. 2.

It is understood that the TEC Convection Radiator 340, TEC Fluid Heat Exchanger 265, Control Module 275, Battery 280, Fan 261, Hot Radiator 325, and TEC Radiator 320 identified in the various figures do not necessarily refer to the same part or part design. These parts must be specifically designed for the intended configuration and application, although the design objectives and principles of operation are the same. It is understood the battery 280 may be one or more and may be any commercially available type—single use or rechargeable, and scaled for the desired system operating time. A rechargeable battery may use any method for recharging.

The batteries indicated for all the TE Cooler systems are anticipated to be Lithium ion batteries due to their superior current capacity to weight ratio. These batteries may take on various forms, to include but not limited to single use or rechargeable with a modular quick-replacement feature. The preferred rechargeable battery is the LiFePO4 model 18650 with a minimum 1350 mAh capacity. Use of alternative batteries is also envisioned.

The Convection TEC System (FIG. 4) and Conduction TEC Head Band Systems (FIGS. 7, 9, 18) and the Remote Conduction TEC Systems (FIGS. 15, 19) are suitable for use in many environments and for many applications to include but not limited for helmets worn in sports, motorcycles, bicycles, special racing automobiles, welding helmets, firemen, SWAT teams, remote oil rigs, hard hats for industrial construction, mining and of course the military. Depending on the application one of these systems may be preferred over the others. In particular the Hard Hat Fluid Conduction TEC System (FIG. 9) is ideally suited for incorporating into hard hats for the construction and mining industries due to the fact that the system is compact and all parts of the systems can easily be incorporated into and on the hard hats with remote battery for long operating time. In addition, for the Hard Hat Fluid Conduction TEC System the hard hat may be configured to exclude dust ridden air from entering the helmet.

Comparing the various types and options for TE Head Cooling; namely Convection, Direct Conduction, Fluid Conduction, Air Conduction, Remote Fluid Conduction, Remote Air Conduction, a combination of Direct and Fluid Conduction, a combination of Direct and Air Conduction, a combination of Direct Conduction and Remote Fluid Conduction and a combination of Direct Conduction and Remote Air Conduction the preferred approach is Fluid Conduction (FIGS. 8-13).

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A thermal electric cooling (“TEC”) system for a helmet, comprising:
one or more TEC chips in thermally conductive communication with a hot radiator on a hot side and a TEC radiator on a cold side, the TEC chips attached to a helmet with the hot radiator positioned on an exterior side of the helmet and the TEC radiator on an interior side of the helmet, the TEC chips further controlled by a controller unit attached to a battery, the controller unit comprising a variable temperature setting for modulating the current flow from the battery to the TEC chips.

2. The TEC system for a helmet of claim 1, further comprising:
the hot radiator further comprises a fan connected to the controller and battery for assisting the removal of hot air.

3. The TEC system for a helmet of claim 2, further comprising:
the TEC radiator further comprises a fan connected to the controller and battery for assisting the moving air over the TEC radiator and circulating the air in the helmet; and,
the helmet further comprising an air intake and channel for deliver air external to the helmet to the TEC radiator fan.

4. The TEC system for a helmet of claim 3, further comprising:
a thermocouple inside the helmet in communication with the controller and battery, wherein the controller further comprises a variable temperature setting and, in operation, current to the TEC chips is modulated to maintain the interior helmet temperature setting.

5. The TEC system for a helmet of claim 4, further comprising
a light emitting diode (“LED”) shoe situated on an exterior front surface of the helmet, in communication with the controller and battery for mounting an LED light source.

6. A thermal electric cooling (“TEC”) system for a helmet, comprising:
a TEC headband arranged within the interior of the helmet, the headband comprising a thermally conductive material with a plurality of TEC chips spaced along the material, with the space between each TEC chip being a thermally insulating material, the TEC chips being controlled by a controller unit attached to a battery, the TEC chips having a cool side arrayed towards the interior of the helmet, and a hot side arrayed opposite the interior of the helmet.

7. The TEC system for a helmet of claim 6, further comprising:
a TEC heat dispenser in thermal communication with the hot side of the TEC chips and a fan, the fan in operative control of the controller and battery, and arranged to pass external air over the TEC heat dissipater.

8. A thermal electric cooling (“TEC”) system for a helmet, comprising:
a helmet housing a fluid thermal cooling (“TC”) headband, the TC headband comprising a thermally conductive material and incorporating one or more circumferential hollow tubes for circulation of a cooling fluid;
a fluid drain tube connecting a first end of the one or more circumferential hollow tubes to a TEC fluid heat exchanger intake;
a fluid fill tube connecting a TEC heat exchanger outtake to a pump and then to a second end of the one or more circumferential hollow tubes, the hollow tubes, fluid drain tube, fluid fill tube pump and TEC fluid heat exchanger filled with a thermally conductive fluid;
the TEC heat exchanger further comprising one or more TEC chips having a cold plate on a cold side and a TEC heat dissipater on a hot side, wherein thermally conductive fluid passes from the fluid drain tube into the TEC heat exchanger intake into the cold plate then into the fluid fill tube and pump and into the hollow tubes;
the TEC heat exchanger receiving air flow from a fan, the TEC heat exchange and fan controlled by a controller unit attached to a battery.

9. The TEC system for a helmet of claim 8, wherein the cooling fluid is air.

10. The TEC system for a helmet of claim 8, further comprising:
a thermocouple inside the helmet in communication with the controller and battery, wherein the controller further comprises a variable temperature setting and, in operation, current to the TEC chips is modulated to maintain the interior helmet temperature setting.

11. The TEC system for a helmet of claim 10, further comprising:
a light emitting diode (“LED”) shoe situated on an exterior front surface of the helmet, in communication with the controller and battery for mounting an LED light source.
